(19) United States
(12) Patent Application Publication
(10) Pub. No.: US 2015/0243860 A1
(43) Pub. Date: Aug. 27, 2015

(54) LIGHT-EMITTING DEVICE

(71) Applicant: Formosa Epitaxy Incorporation, Taoyuan County (TW)

(72) Inventors: Lung-Kuan Lai, Taoyuan County (TW); Jen-Chih Li, Taoyuan County (TW); Yi-Chun Chen, Taoyuan County (TW); Shyi-Ming Pan, Taoyuan County (TW)

(21) Appl. No.: 14/623,491

(22) Filed: Feb. 16, 2015

(30) Foreign Application Priority Data
Feb. 25, 2014 (TW) 103106212

(51) Int. Cl. H01L 33/60; H01L 33/50; H01L 33/62

(52) U.S. Cl. CPC H01L 33/60; H01L 33/62; H01L 33/50

(57) ABSTRACT

A light-emitting device including a first substrate, a second substrate disposed above the first substrate a barrier structure disposed on the first substrate and surrounding the second substrate, at least one light-emitting semiconductor unit disposed on the second substrate and a glue disposed between the light-emitting semiconductor unit and the barrier structure is provided. The barrier structure is separated from the second substrate by a distance R in a direction parallel to the first substrate. At least one portion of the glue is filled into the distance R between the barrier structure and the second substrate.

### CROSS-REFERENCE TO RELATED APPLICATION

This application claims the priority benefit of Taiwan application serial no. 103106212, filed on Feb. 25, 2014. The entirety of the above-mentioned patent application is hereby incorporated by reference herein and made a part of this specification.

### BACKGROUND OF THE INVENTION

1. Field of the Invention

The present invention generally relates to a light-emitting device, in particular, to a semiconductor light-emitting device.

2. Description of Related Art

The light-emitting principle of light-emitting semiconductor units such as light-emitting diode (LED) chip is utilizing the characteristics specially owned by semiconductors, and being different from the light-emitting principles of regular fluorescent lamps or incandescent lamps. Thus, light-emitting semiconductor units have advantages of long lifetime, low power consumption, and being broadly used in our daily life.

In general, the light-emitting devices using light-emitting semiconductor units as light sources comprise the light-emitting semiconductor units disposed in lead frames having bowl-shaped recesses and covered with sealing glue to protect the light-emitting semiconductor units. In some technologies, phosphor is added to the sealing glue in order to convert the light emitted by the light-emitting semiconductor units with wavelength in a specific range to light with wavelength in another range, such that the light-emitting devices can emit white or other colors light according to applications, such as the disclosure of China Invention Patent Publication No. 103022324. There are also technologies dispose light-emitting semiconductor units in an assigned plain area, which has frames around itself, of a substrate, wherein the frame is directly connected to the substrate and surrounding the light-emitting semiconductor units, so as to become a barrier structure for the sealing glue covered the light-emitting semiconductor units, such as the disclosures of China Invention Patent No. 102544325 or US Invention Patent No. 8,373,182.

### SUMMARY OF THE INVENTION

Since the heat generated during the illumination of light-emitting semiconductor units will degrade the lifetime of the light-emitting semiconductor units, it is usually to directly dispose the light-emitting semiconductor units on heat-sink substrates which are expensive. According to the related art, since frames or barrier structures and light-emitting semiconductor units are disposed on an identical heat-sink substrate, the heat-sink substrate need to sacrifice a portion of its surface for the frames/barrier structures or integrate with the frames, therefore the usage of heat-sink substrates is wasting. Meanwhile, since the space forming from the substrates and the frames/barrier structures is limited, the height of the barrier structure will interfere with the process of soldering the light-emitting semiconductor units to the substrate and the wiring between light-emitting semiconductor units. And the situation of overflowing is easy to happen during the filling of sealing glue. Therefore, the difficulty and the complexity of the process are increased, and the yield rate and the cost of the light-emitting devices are affected.

In order to overcome the disadvantages of the conventional technology, the present invention provides a light-emitting device and a manufacturing method thereof, wherein the light-emitting device of the present invention includes a first substrate, a second substrate being disposed on the first substrate, a barrier structure being disposed on the first substrate and surrounding the second substrate, at least one light-emitting semiconductor unit being disposed on the second substrate, and a glue being disposed between the light-emitting semiconductor unit and the barrier structure. The barrier structure is separated from the second substrate to form a gap within a distance R in a direction parallel to the first substrate, and at least one portion of the glue is disposed in the gap.

According to an embodiment of the present invention, the distance R is in a specific range, which is 0<R≦0.3 mm.

According to an embodiment of the present invention, the distance R is equal or close to 0.1 mm.

According to an embodiment of the present invention, the glue surrounds the light-emitting semiconductor unit and exposes a light-emitting surface of the light-emitting semiconductor unit.

According to an embodiment of the present invention, the glue includes a reflecting material to reflect the light emitting from the light-emitting semiconductor unit.

According to an embodiment of the present invention, the light-emitting semiconductor unit has a wavelength conversion layer.

According to an embodiment of the present invention, the light-emitting semiconductor unit has a first height H1 in a direction perpendicular to the first substrate. The barrier structure is higher then the second substrate by a height H2, wherein H1<H2≦(3·H1).

According to an embodiment of the present invention, a material of the barrier structure includes a light-absorbing material.

According to an embodiment of the present invention, the first substrate includes a first base and an electrode pattern disposed on the first base. The second substrate includes a second base, a conductive pattern disposed on the second base, and a group of conductive holes disposed corresponding to at least one portion of the electrode pattern on the first base and coupled to the conductive pattern. The conductive holes penetrate the second base.

According to an embodiment of the present invention, the first electrode and the second electrode of the light-emitting semiconductor unit are respectively disposed on the opposite surfaces of the light-emitting semiconductor unit respectively. One of the first electrode and the second electrode is electrically connected to one of the conductive holes through the conductive pattern.

According to an embodiment of the present invention, the first electrode and the second electrode of the light-emitting semiconductor unit are disposed on the same side of the light-emitting semiconductor unit. One of the first electrode and the second electrode is electrically connected to one of the conductive holes through the conductive pattern.

According to an embodiment of the present invention, the second substrate exposes an adhesive region of the first substrate. The barrier structure is disposed on the adhesive region of the first substrate and exposed the light-emitting surface of the light-emitting semiconductor unit. The barrier structure has a bonding surface facing the first substrate and parallel to the first substrate. The light-emitting device further includes an adhesive layer locating between the bonding surface and the first substrate and connecting with the bonding surface and the first substrate.

The present invention further provides a light-emitting device including a first substrate, a second substrate disposing on the first substrate, a barrier structure disposing on the first substrate and surrounding the second substrate, at least one light-emitting semiconductor unit being disposed on the second substrate, and a glue being disposed between the light-emitting semiconductor unit and the barrier structure. The light-emitting semiconductor unit has a first height H1 in a direction perpendicular to the first substrate. The barrier structure is higher then the second substrate by a height H2 in the direction perpendicular to the first substrate, wherein H1<H2≦(3·H1).

According to an embodiment of the present invention, the barrier structure is separated from the second substrate to form a gap within a distance R in a direction parallel to the first substrate, and at least one portion of the glue is disposed in the gap; and wherein the glue surrounds the light-emitting semiconductor unit and exposes a light-emitting surface of the light-emitting semiconductor unit.

According to an embodiment of the present invention, 0<R≦0.3 mm.

According to an embodiment of the present invention, the distance R is equal or close to 0.1 mm.

According to an embodiment of the present invention, a material of the glue comprises a reflecting material to reflect the light emitting from the light-emitting semiconductor unit.

According to an embodiment of the present invention, the light-emitting semiconductor unit has a wavelength conversion layer.

According to an embodiment of the present invention, a material of the barrier structure comprises a light-absorbing material.

According to an embodiment of the present invention, the first substrate comprises a first base and an electrode pattern disposed on the first base; the second substrate comprises a second base, a conductive pattern disposed on the second base, and a group of conductive holes disposed corresponding to at least one portion of the electrode pattern on the first base and coupled to the conductive pattern; and wherein the conductive holes penetrate the second base.

According to an embodiment of the present invention, a first electrode and a second electrode of the light-emitting semiconductor unit are respectively disposed on the two opposing surfaces of the light-emitting semiconductor unit, and one of the first electrode and the second electrode is electrically connected to one of the conductive holes through the conductive pattern.

According to an embodiment of the present invention, a first electrode and a second electrode of the light-emitting semiconductor unit are disposed on the same side of the light-emitting semiconductor unit, and one of the first electrode and the second electrode is electrically connected to one of the conductive holes through the conductive pattern.

According to an embodiment of the present invention, the second substrate exposes an adhesive region of the first substrate, the barrier structure is disposed on the adhesive region and exposed a light-emitting surface of the light-emitting semiconductor unit, and the barrier structure has a bonding surface which is facing the first substrate and parallel to the first substrate; and the light-emitting device further comprises an adhesive layer disposed between the bounding surface and the first substrate and contacting with the bonding surface and the first substrate.

Accordingly, since the barrier structure is disposed beside the second substrate carrying the light-emitting semiconductor unit in the light-emitting device of the present invention, which means that the light-emitting device is carrying the barrier structure with the first substrate, the second won't need to reserve surface or volume for carrying or forming the barrier structure. Therefore, the usage of the high cost second substrate can be more effective, and the reduction of the usage and the cost of material can reduce the cost of the light-emitting device. Meanwhile, a gap is further kept between the barrier structure and the second substrate in the light-emitting device of the present invention, and the process of disposing light-emitting semiconductor units and glues can be simplify through the highly associated optimization of the barrier structure, and the manufacture and the yield rate of the light-emitting device can be improved.

To make the aforesaid features and advantages of the invention more comprehensible, several embodiments accompanied with figure s are described in detail below to further describe the invention in details.

### BRIEF DESCRIPTION OF THE DRAWINGS

FIGS. 1A through 1E are cross-sectional views illustrating different stages of a process of manufacturing a light-emitting device according to one embodiment of the present invention.

FIGS. 2A through 2E are top views illustrating different stages of a process of manufacturing a light-emitting device according to one embodiment of the present invention.

FIG. 3 is a cross sectional view along the B-B′ line shown in FIG. 2B.

FIG. 4 is a cross sectional view along the C-C′ line shown in FIG. 2D.

FIG. 5 is a cross sectional view along the D-D′ line shown in FIG. 2E.

### DESCRIPTION OF THE EMBODIMENTS

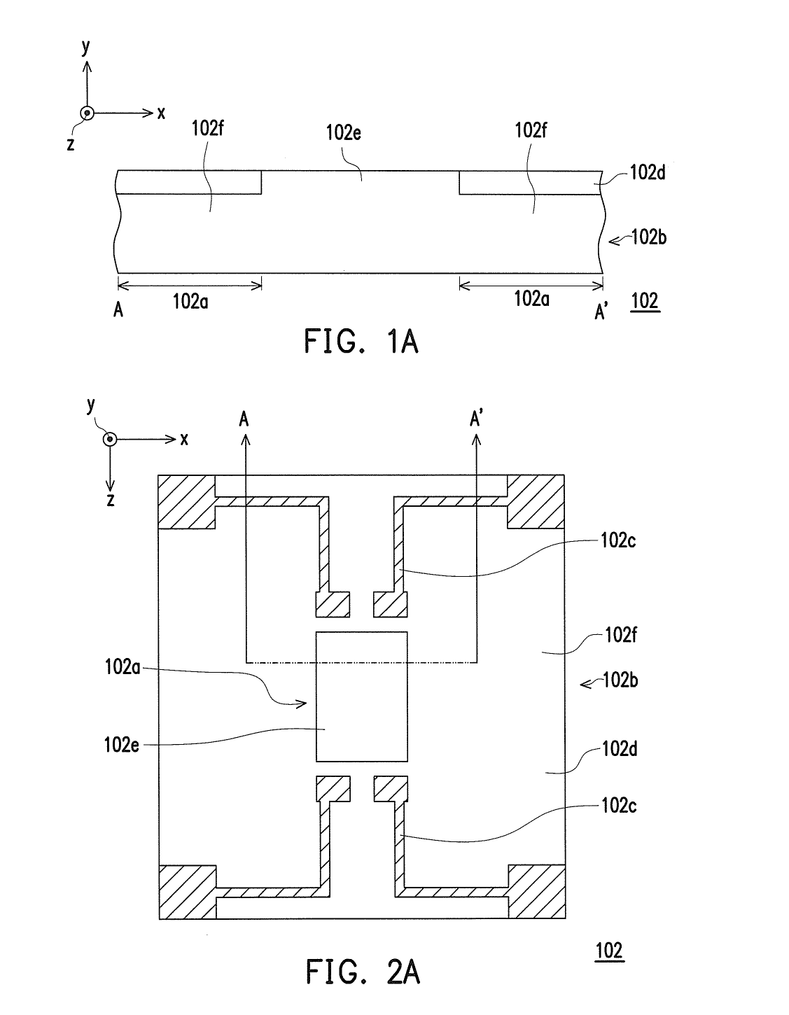

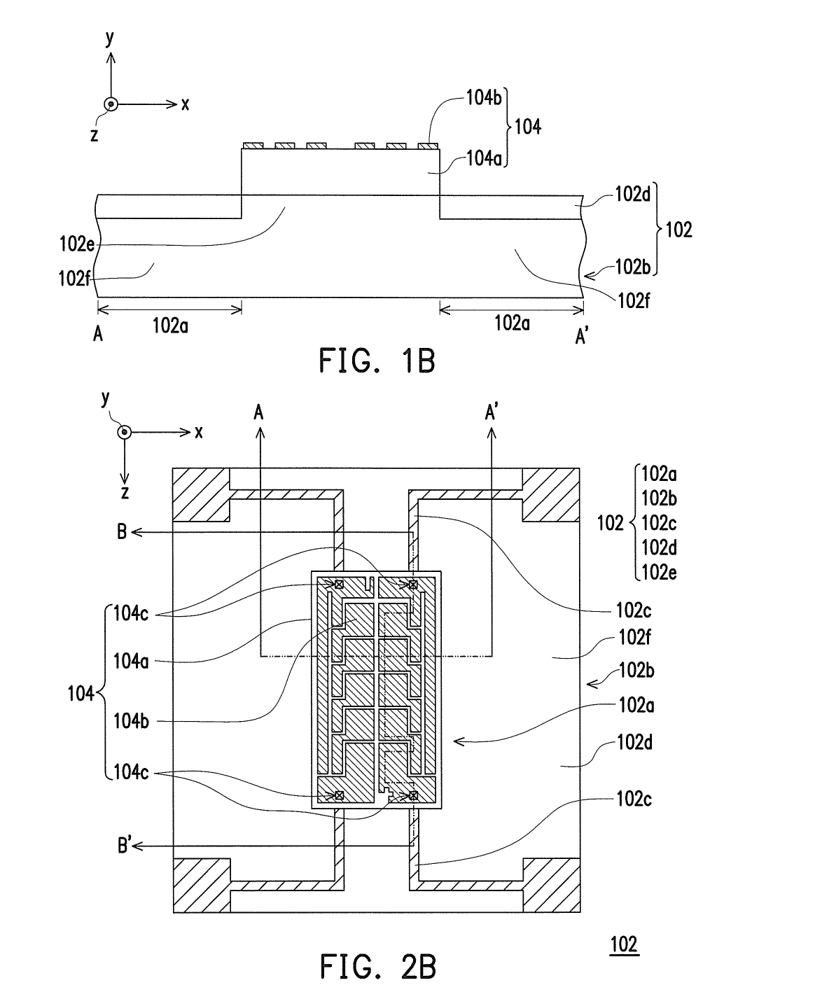

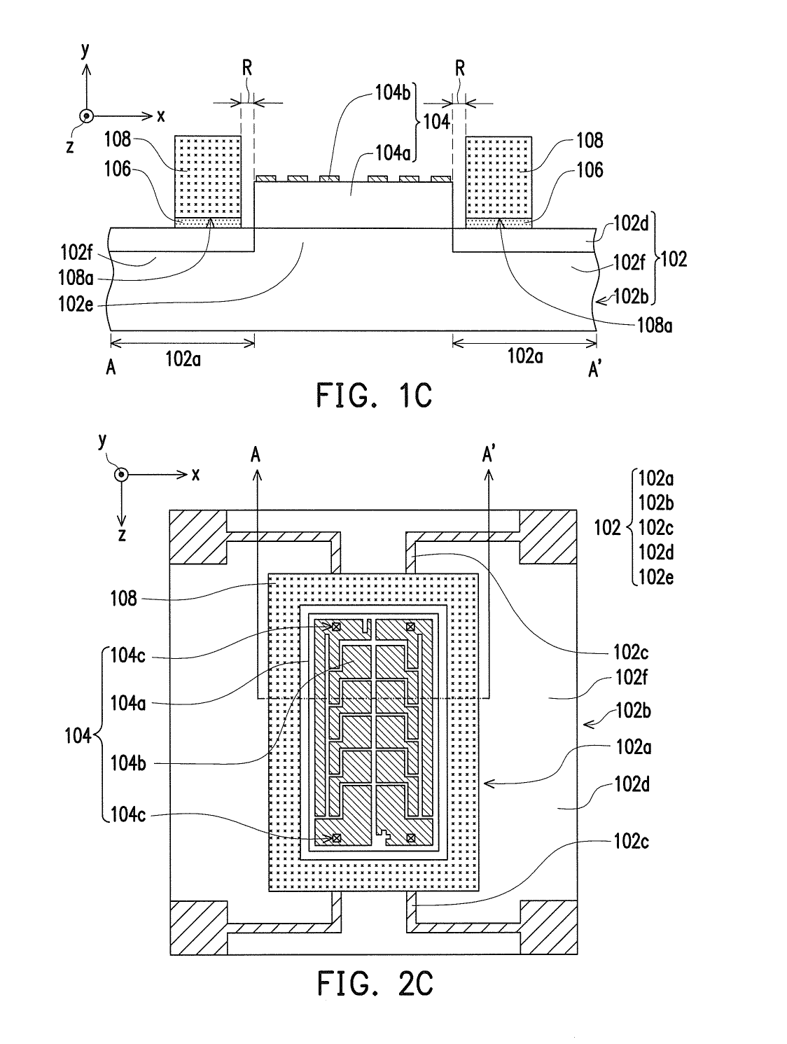

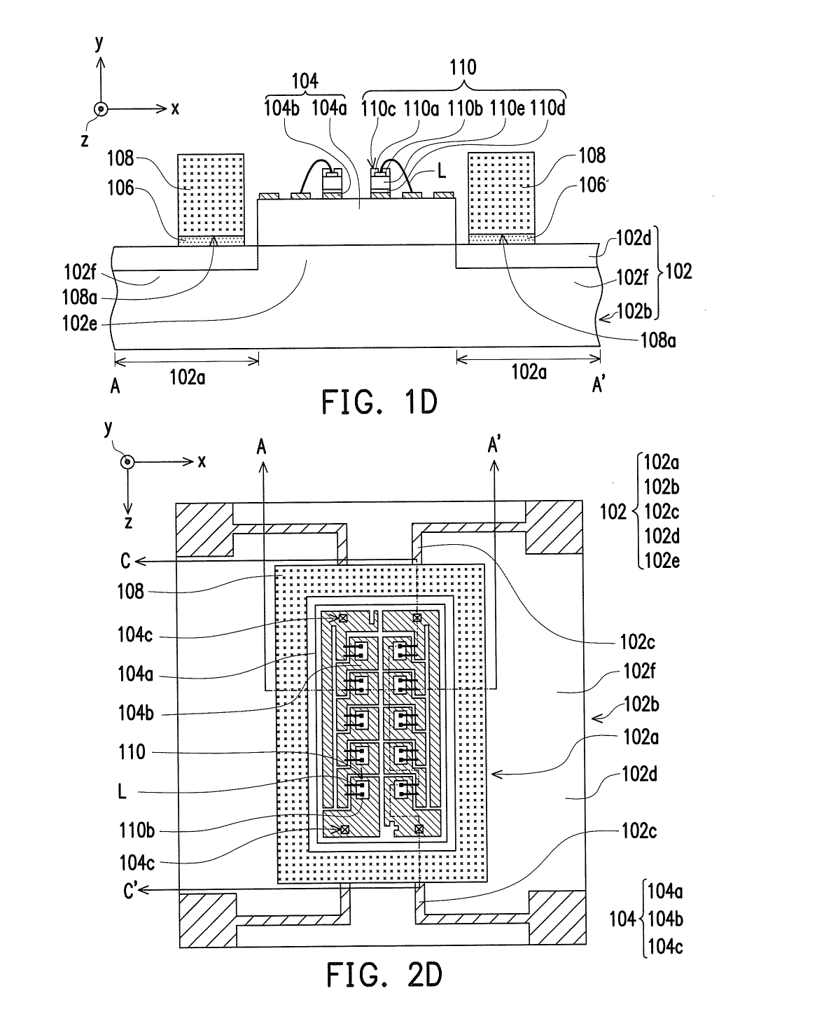

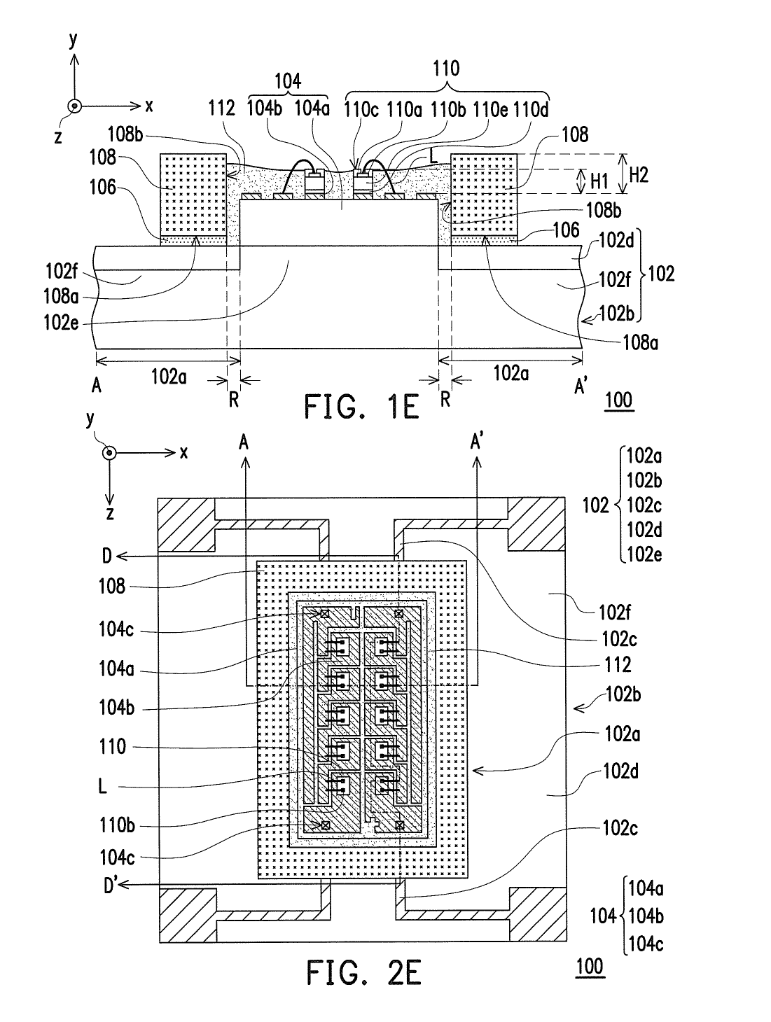

FIGS. 1A through 1E are cross-sectional views illustrating different stages of a process of manufacturing a light-emitting device 100 according to one embodiment of the present invention. FIGS. 2A through 2E are top views illustrating different stages of a process of manufacturing the light-emitting device 100 according to one embodiment of the present invention. FIG. 1A through 1E are particularly corresponded to the line A-A′ in FIG. 2A through 2E. Firstly, referring to FIG. 1A and FIG. 2A, a first substrate 102 is provided. The first substrate 102 includes a first base 102b and an electrode pattern 102c being disposed on the first base 102b (illustrated in FIG. 2A). In the embodiment, in order to get better heat dissipation performance of the light-emitting device 100 of the present invention, the first substrate 102 may be a metal core printed circuit board (MCPCB). More particularly, a material of the first base 102b includes metals, such as bronze, aluminum, bronze alloy or aluminum alloy and etc. The first base 102b can have a protruding part 102e and a stage part 102f. The stage part 102f is disposed beside the protruding part 102e and, comparing with the protruding part 102e, the stage part 102f is concave. That is, the thickness of the stage part 102f is smaller then the thickness of the protruding part 102e, but not limited thereto. For example, in other embodiments of the present invention, the thickness of the stage part 102f may also be larger then or equal to the thickness of the protruding part 102e. The first substrate 102 further includes an insulation layer 102d. The insulation layer 102d is disposed on the stage part 102f of the first base 102b and exposed the protruding part 102e. A portion of the insulation layer 102d is sandwiched between the electrode pattern 102c and the first base 102b, such that the electrode pattern 102c is electrically insulated to the first base 102b. Nevertheless, the above descriptions about the first substrate 102 are taken as examples, and the descriptions of the first substrate 102 are not restricted in the present invention. In other embodiments, the first substrate 102 may also be other type of circuit board.

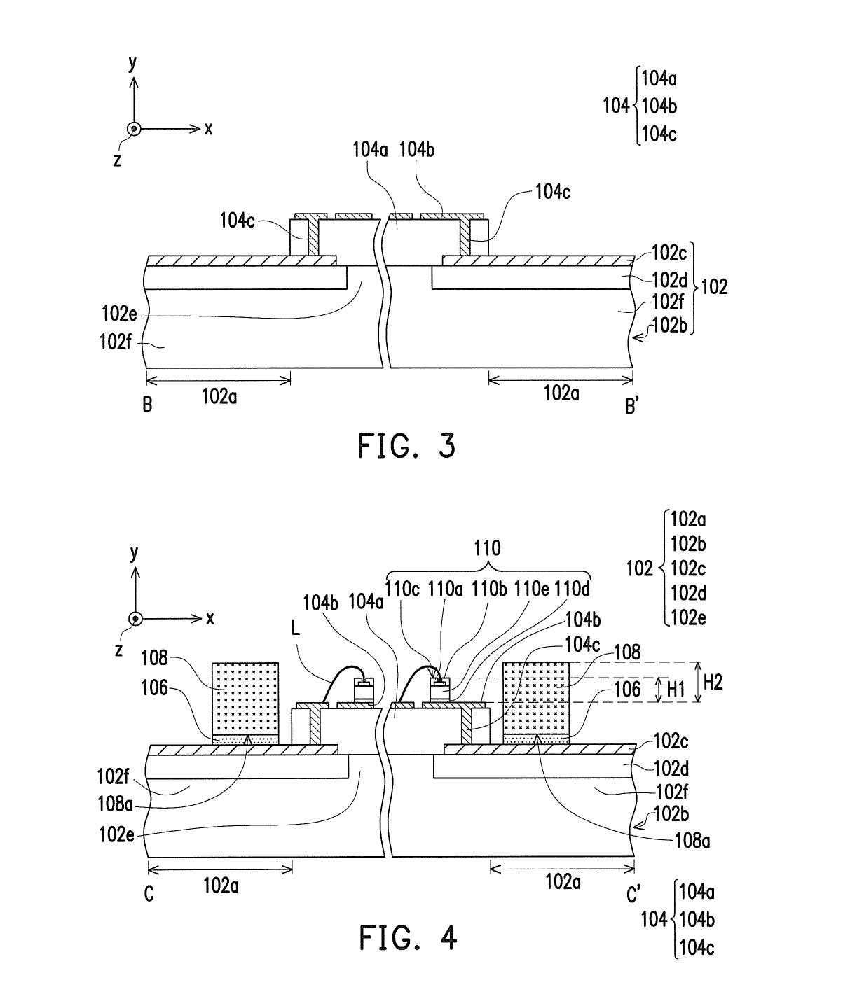

Then, referring to FIGS. 1B and 2B, the first substrate 102 and a second substrate 104 are bounded together. When the first substrate 102 and the second substrate 104 are bonded together, the first substrate 102 can also be electrically connected with the second substrate 104 at the same time. The following will descript the detail accompanied with FIG. 3. FIG. 3 is cross sectional view along the B-B′ line shown in FIG. 2B. Referring to FIGS. 1B, 2B and 3, the second substrate 104 includes a second base 104a, a conductive pattern 104b disposed on the second base 104a and at least one group of conductive holes 104c disposed corresponding to at least one portion of the electrode pattern 102c on the first base 102b and coupled to the conductive pattern 104b. Each group of the conductive holes 104c can include one or more conductive holes 104c. In the present embodiment, a plurality of conductive holes 104c of every group of conductive holes 104c are electrically connected to first electrodes 110d and second electrodes 110b of light-emitting semiconductor units 110 respectively (illustrated in FIGS. 2D and 4). Each of the conductive holes 104c penetrates the second base 104a and being electrically coupled to the conductive pattern 104b. As illustrated in FIG. 3, when the first substrate 102 and the second substrate 104 are bonded together, the conductive holes 104c are electrically connected to the electrode pattern 102c, and the first substrate 102 is therefore electrically connected with the second substrate 104. Besides, as illustrated in FIG. 2C, in this embodiment, the conductive pattern 104b includes a plurality of “ [symbol] ” shaped patterns being closely adjacent to each other and a plurality of “L” shaped patterns being disposed on the periphery of the second substrate 104 and surrounding the “ [symbol] ” shaped patterns. Therefore, the light-emitting semiconductor unit 110 can be disposed in the most tightly form (illustrated in FIG. 2D), and fully utilizing the high heat dissipation function of the second substrate 104, and increasing the light-emitting intensity of the light-emitting device 100 of the present invention simultaneously.

Referring to FIGS. 1B, 2B and 3, after the first substrate 102 and the second substrate 104 are bonded together, the second substrate 104 is disposed on the first substrate 102 and exposed an adhesive area 102a of the first substrate 102. More particularly, in this embodiment, the second substrate 104 may be disposed on the protruding part 102e of the first substrate 102 and exposed at least one portion of the stage part 102f of the first substrate 102. The light-emitting semiconductor unit 110 (illustrated in FIG. 1E) disposed on the second substrate 104 may be overlapped with the protruding part 102e, and therefore the heat generated from the light-emitting semiconductor unit 110 during driving can be quickly transferred to the outside of the light-emitting device 100 (illustrated in FIG. 1E) through the protruding part 102e and the second substrate 104 having good heat dissipation performance, and the lifetime of the light-emitting device 100 can be further increased. In the present embodiment, the adhesive area 102a can be a ring-shaped area, for example a “□” shaped area. The material of the second base 104a of the second substrate 104 includes sapphire, silicon, silicon carbide, diamond or AlN and etc. But, the present invention is not limited by the abovementioned. In other embodiments, the shaped of the adhesive area 102a and the material of the second substrate 104 can have other design according to the actual demand.

As illustrated in FIG. 3, when the first substrate 102 and the second substrate 104 are bonded together, the conductive holes 104c of the second substrate 104 is disposed corresponding to at least one portion of electrode pattern 102c on the first base 102b. More particularly, in the embodiments, the conductive holes 104c is overlapped with the electrode pattern 102c in a direction y, wherein the direction y is perpendicular to the second base 104a. But, the present invention is not limited thereto. In other embodiments, the conductive holes 104c can also not be overlapped with the electrode pattern 102c in the direction y, and being electrically connected to the electrode pattern 102c by other conductive components.

Next, referring to FIGS. 1C and 2C, a barrier structure 108 is connected to the adhesive area 102a of the first substrate 102 through an adhesive layer 106. After the barrier structure 108 is connected to the adhesive area 102a of the first substrate 102, the barrier structure 108 is disposed on the adhesive area 102a of the first substrate 102 and surrounds the second substrate 104. Particularly, the barrier structure 108 is separated from the second substrate 104 to form a gap within a distance R in a direction x parallel to the first substrate 102, wherein 0<R≦0.3 mm. Furthermore, in the embodiment, the distance R may be equal or close to 0.1 mm, but the present invention is not limited thereto. The barrier structure 108 has a bonding surface 108a facing the first substrate 102 and being parallel to the first substrate 102. The adhesive layer 106 is located between the bonding surface 108a and the first substrate 102 and contacted with the bonding surface 108a and the first substrate 102. In the embodiment, for example, the barrier structure 108 may be a ring-shaped structure surrounding the second substrate 104, and the material of the barrier structure 108 is insulation material, in order to protect the light-emitting semiconductor unit 110 (illustrated in FIG. 1E) being carried by the second substrate 104 from being struck by lightning and being penetrated by electrostatic discharge (ESD). Note that the shape and the material of the barrier structure 108 are merely exemplary and should not be construed as limitations of the present invention. Moreover, in the embodiment of FIGS. 1C and 2C, the adhesive layer 106 and the barrier structure 108 are substantially aligned, for example. However, the invention is not limited thereto. In other embodiments, the adhesive layer 106 may also be expanded by the pressure generated in the process of the bonding the barrier structure 108 and the first substrate 102 together, and being extended toward the second base 104a to increase the yield and reliability of the light-emitting device 100. In other words, the invention is not limited to separating the adhesive layer 106 and the second base 104a by a distance R. In other embodiments, the adhesive layer 106 may also be expanded to the second base 104a by the pressure and being contacted with the second base 104a.

Next, referring to FIGS. 1D and 2D, the at least one light-emitting semiconductor unit 110 is fixed on the second substrate 104, and the light-emitting semiconductor unit 110 is electrically connected to the second substrate 104. More particularly, in the embodiment, the light-emitting semiconductor unit 110 may have a first electrode 110d and a second electrode 110b being disposed on the two opposite surfaces of the light-emitting semiconductor unit 110 respectively. The first electrode 110d and the second electrode 110b may be disposed on the opposite sides corresponding to a light-emitting layer 110e of the light-emitting semiconductor unit 110, but not limited thereto. For example, in other embodiments of the present invention, the first electrode 110d and the second electrode 110b can also be disposed on the same side of the light-emitting semiconductor unit 110. The light-emitting semiconductor unit 110 may selectively include a wavelength conversion layer 110a (a phosphor layer, for example) covering the light emitting layer 110e. One of the first electrode 110d and the second electrode 110b (the first electrode 110d, for example) is directly bonded with the conductive pattern 104b, and electrically connected with the second substrate 104. Another one of the first electrode 110d and the second electrode 110b (the second electrode 110b, for example) is electrically connected to the conductive pattern 104b through a wire L and electrically connected to the second substrate 104. Note that the form of the light-emitting semiconductor unit 110 and the way of electrical connection between the light-emitting semiconductor unit 110 and the second substrate 104 are merely exemplary and should not be construed as limitations of the present invention. In other embodiments, the light-emitting semiconductor unit 110 may also be in other forms, and the manufacturer can utilize a proper way to electrically connect the light-emitting semiconductor unit 110 to the second substrate 104 according to the form of the light-emitting semiconductor unit 110. For example, in other embodiments, when the first electrode 110d and the second electrode 110b of the light-emitting semiconductor unit 110 are disposed at the same side of the light-emitting semiconductor unit 110, the manufacturer can further utilize a method of flip chip to electrically connect the light-emitting semiconductor unit 110 to the second substrate 104. Besides, in other embodiments of the present invention, the step disclosed in FIGS. 1D and 2D can be prior to the step disclosed in FIGS. 1C and 2C. That is, after the light-emitting semiconductor unit 110 is disposed on the second substrate 104, the barrier structure 108 will be disposed on the first substrate 102, and therefore the process of disposing the light-emitting semiconductor unit 110 won't be affect by the height of the barrier structure 108.

FIG. 4 is cross sectional view along the C-C′ line shown in FIG. 2D. Referring to FIG. 4, after the light-emitting semiconductor unit 110 is electrically to the second substrate 104 and the light-emitting semiconductor units 110 are electrically connected in series or in parallel, the light-emitting semiconductor units 110 can electrically connect to an external power for driving the light-emitting semiconductor unit 110 through the conductive pattern 104b, the conductive holes 104c and the electrode pattern 102c. Besides, after the light-emitting semiconductor unit 110 is fixed on the second substrate 104, the light-emitting semiconductor unit 110 is surrounded by the barrier structure 108, and the light-emitting surface 110c of the light-emitting semiconductor unit 110 is exposed by the barrier structure 108. In the embodiment, a material of the barrier structure 108 may include a light-absorbing material, and the barrier structure 108 may be higher then the light-emitting semiconductor unit 110. For example, the light emitting semiconductor unit 110 has a first height H1 in a direction y perpendicular to the first substrate 102, and the barrier structure 108 is higher then the second substrate 104 by a height H2 in the direction y perpendicular to the first substrate 102, wherein H1<H2≦(3·H1). Consequently, the light emitted toward two sides of the light-emitting semiconductor unit 110 can be absorbed by the barrier structure 108, and the light-emitting device 100 (as shown in FIG. 1E) can be directional, and the process of disposing the light-emitting semiconductor unit 110 on the second substrate 104 won't be interfered at the same time. However, the present invention is not limited thereto. In other embodiments, the material of the barrier structure 108 and the height of the barrier structure 108 corresponding to the light-emitting semiconductor unit 110 can all be designed properly according to the optical characteristic of the light-emitting device 100 intended to achieve.

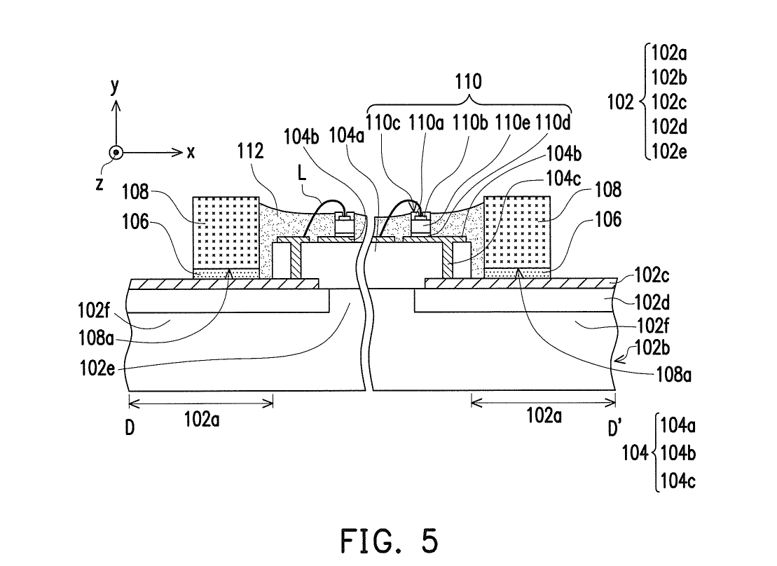

FIG. 5 is a cross sectional view along the D-D′ line shown in FIG. 2E. Next, referring to FIGS. 1E, 2E and 5, the light-emitting device 100 further includes a glue 112 filled in an area surrounding by the barrier structure 108, wherein the area includes an area between the barrier structure 108 and the light-emitting semiconductor unit 110 and an area between one light-emitting semiconductor unit 110 and another light-emitting semiconductor unit 110. The glue 112 surrounds the light-emitting semiconductor unit 110 and exposes a light emitting surface 110c of the light emitting semiconductor unit 110. The glue 112 can selectively include a reflecting material to reflect the light emitting from the light-emitting semiconductor unit 110. The glue 112 having reflecting property can guide portion of the light emitted from the two side of the light-emitting semiconductor unit 110 to a direction that is more identical to the direction y being perpendicular to the first substrate 102, and the intensity of light emitted from light-emitting device 100 in or near to the direction y can be improved. However, the present invention is not limited thereto. In other embodiments, the material of the glue 112 of the light-emitting device 100 can exclude reflecting material.

It should be noted that the glue 112 is not only disposed between the light-emitting semiconductor unit 110 and the barrier structure 108, but also being disposed between the barrier structure 108 and the second substrate 104. Namely, at least one portion of the glue 112 is disposed in the gap between the barrier structure 108 and the second substrate 104. In other words, the adhesive surface 108a of the barrier structure 108 facing the first substrate 102 may connect to the first substrate 102 through the adhesive layer 106, and the side surface 108b of the barrier structure 108 facing the second substrate 104 can also connect to the second substrate 104 through the glue 112, and therefore, the barrier structure 108 has more adhesion area comparing to the prior art, and being more firmly fixed in the light-emitting device 100. Moreover, since the barrier structure 108 is disposed beside the second substrate 104, which means that the light-emitting device 100 carries the barrier structure 108 with the first substrate 102 rather than the second substrate 104, and there is no need to reserve surface or space for carrying or forming the barrier structure 108 on the second substrate 104. Therefore, the reduction of the usage and the cost of material of the second substrate 104 can reduce the cost of the light-emitting device 100.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A light-emitting device, comprising:
a first substrate;
a second substrate disposed on the first substrate;
a barrier structure disposed on the first substrate and surrounding the second substrate;
at least one light-emitting semiconductor unit disposed on the second substrate; and
a glue disposed between the light-emitting semiconductor unit and the barrier structure, wherein the barrier structure is separated from the second substrate to form a gap within a distance R in a direction parallel to the first substrate, and at least one portion of the glue is disposed in the gap.

2. The light-emitting device as claimed in claim 1, wherein 0<R≦0.3 mm.

3. The light-emitting device as claimed in claim 2, wherein the distance R is equal or close to 0.1 mm.

4. The light-emitting device as claimed in claim 1, wherein the glue surrounds the light-emitting semiconductor unit and exposes a light-emitting surface of the light-emitting semiconductor unit.

5. The light-emitting device as claimed in claim 4, wherein a material of the glue comprises a reflecting material to reflect the light emitting from the light-emitting semiconductor unit.

6. The light-emitting device as claimed in claim 4, wherein the light-emitting semiconductor unit has a wavelength conversion layer.

7. The light-emitting device as claimed in claim 1, wherein the light-emitting semiconductor unit has a first height H1 in a direction perpendicular to the first substrate, and the barrier structure is higher then the second substrate by a height H2, wherein H1<H2≦(3·H1).

8. The light-emitting device as claimed in claim 1, wherein a material of the barrier structure comprises a light-absorbing material.

9. The light-emitting device as claimed in claim 1, wherein the first substrate comprises a first base and an electrode pattern disposed on the first base; the second substrate comprises a second base, a conductive pattern disposed on the second base, and a group of conductive holes disposed corresponding to at least one portion of the electrode pattern on the first base and coupled to the conductive pattern; and wherein the conductive holes penetrate the second base.

10. The light-emitting device as claimed in claim 9, wherein a first electrode and a second electrode of the light-emitting semiconductor unit are respectively disposed on the two opposing surfaces of the light-emitting semiconductor unit, and one of the first electrode and the second electrode is electrically connected to one of the conductive holes through the conductive pattern.

11. The light-emitting device as claimed in claim 9, wherein a first electrode and a second electrode of the light-emitting semiconductor unit are disposed on the same side of the light-emitting semiconductor unit, and one of the first electrode and the second electrode is electrically connected to one of the conductive holes through the conductive pattern.

12. The light-emitting device as claimed as claim 1, wherein the second substrate exposes an adhesive region of the first substrate, the barrier structure is disposed on the adhesive region and exposed a light-emitting surface of the light-emitting semiconductor unit, and the barrier structure has a bonding surface which is facing the first substrate and parallel to the first substrate; and the light-emitting device further comprises an adhesive layer disposed between the bounding surface and the first substrate and contacting with the bonding surface and the first substrate.

13. A light-emitting device, comprising:
a first substrate;
a second substrate disposed on the first substrate;
a barrier structure disposed on the first substrate and surrounding the second substrate;
at least one light-emitting semiconductor unit disposed on the second substrate; and
a glue disposed between the light-emitting semiconductor unit and the barrier structure, wherein the light-emitting semiconductor unit has a first height H1 in a direction perpendicular to the first substrate, and the barrier structure is higher then the second substrate by a height H2, wherein H1<H2≦(3·H1).

14. The light-emitting device as claimed as claim 13, wherein the barrier structure is separated from the second substrate to form a gap within a distance R in a direction parallel to the first substrate, and at least one portion of the glue is disposed in the gap; and wherein the glue surrounds the light-emitting semiconductor unit and exposes a light-emitting surface of the light-emitting semiconductor unit.

15. The light-emitting device as claimed as claim 14, wherein 0<R≦0.3 mm.

16. The light-emitting device as claimed in claim 14, wherein the distance R is equal or close to 0.1 mm.

17. The light-emitting device as claimed in claim 13, wherein a material of the glue comprises a reflecting material to reflect the light emitting from the light-emitting semiconductor unit.

18. The light-emitting device as claimed in claim 13, wherein the light-emitting semiconductor unit has a wavelength conversion layer.

19. The light-emitting device as claimed in claim 13, wherein a material of the barrier structure comprises a light-absorbing material.

20. The light-emitting device as claimed in claim 13, wherein the first substrate comprises a first base and an electrode pattern disposed on the first base; the second substrate comprises a second base, a conductive pattern disposed on the second base, and a group of conductive holes disposed corresponding to at least one portion of the electrode pattern on the first base and coupled to the conductive pattern; and wherein the conductive holes penetrate the second base.

21. The light-emitting device as claimed in claim 20, wherein a first electrode and a second electrode of the light-emitting semiconductor unit are respectively disposed on the two opposing surfaces of the light-emitting semiconductor unit, and one of the first electrode and the second electrode is electrically connected to one of the conductive holes through the conductive pattern.

22. The light-emitting device as claimed in claim 20, wherein a first electrode and a second electrode of the light-emitting semiconductor unit are disposed on the same side of the light-emitting semiconductor unit, and one of the first electrode and the second electrode is electrically connected to one of the conductive holes through the conductive pattern.

23. The light-emitting device as claimed as claim 13, wherein the second substrate exposes an adhesive region of the first substrate, the barrier structure is disposed on the adhesive region and exposed a light-emitting surface of the light-emitting semiconductor unit, and the barrier structure has a bonding surface which is facing the first substrate and parallel to the first substrate; and the light-emitting device further comprises an adhesive layer disposed between the bounding surface and the first substrate and contacting with the bonding surface and the first substrate.
